(19) United States
(12) Patent Application Publication
(10) Pub. No.: US 2025/0015798 A1
(43) Pub. Date: Jan. 9, 2025

(54) GATE DRIVER CIRCUIT

(71) Applicant: ROHM CO., LTD., Kyoto-shi (JP)

(72) Inventor: Hisashi SUGIE, Kyoto-shi (JP)

(21) Appl. No.: 18/762,898

(22) Filed: Jul. 3, 2024

(30) Foreign Application Priority Data
Jul. 4, 2023 (JP) 2023-110261

(51) Int. Cl. H03K 17/687; H02P 27/00

(52) U.S. Cl. CPC H03K 17/6871; H02P 27/00

(57) ABSTRACT

A turn-on circuit is configured to supply a current as a source to the gate of a high-side transistor. A first current source supplies an output current that is switchable between a first current amount and a second current amount that is smaller than the first current amount. A first switch is coupled between a first output node of a first current mirror circuit and the gate of the high-side transistor. A second current source generates a second current. A second switch is coupled between a first output node of a second current mirror circuit and the gate of the high-side transistor.

### CROSS REFERENCE TO RELATED APPLICATIONS

The present invention claims priority under 35 U.S.C. § 119 to Japanese Application No. 2023-110261, filed on Jul. 4, 2023, the entire contents of which being incorporated herein by reference

### BACKGROUND

### 1. Technical Field

The present disclosure relates to a gate driver circuit.

### 2. Description of the Related Art

In many cases, motor driver circuits, DC/DC converters, power conversion apparatuses, etc., employ a half-bridge circuit, an H-bridge-circuit, or a three-phase bridge circuit (which will be collectively referred to as a “bridge circuit” hereafter) employing a power transistor.

FIG. 1 is a circuit diagram of a bridge circuit 10. The bridge circuit 10 includes an upper arm 12 and a lower arm 14 arranged in series between a power supply terminal and a ground terminal. The upper arm 12 includes a high-side transistor MH and a flywheel diode Di coupled in parallel. The lower arm 14 includes a low-side transistor ML and a flywheel diode Di coupled in parallel. An inductor (coil) that functions as a load is coupled to an output terminal of the bridge circuit 10.

The bridge circuit 10 is settable to a state (high-impedance state) ϕ1 in which both the high-side transistor MH and the low-side transistor ML are turned off, a state (high-output state) ϕ2 in which the high-side transistor MH is turned on and the low-side transistor ML is turned off, a state (low-output state) ϕ3 in which the high-side transistor MH is turned off and the low-side transistor ML is turned on. Each of the states ϕ1 through ϕ3 has a current source state (current flows toward the right in the drawing) in which the bridge circuit 10 outputs a current I_{OUT} and a current sink state (current flows toward the left in the drawing) in which the current I_{OUT} is drawn by the bridge circuit 10.

As a result of investigating the bridge circuit shown in FIG. 1, the present inventor has come to recognize the following problems.

Let us consider a case in which the state is switched from the high-impedance state ϕ1 to the high-output state ϕ2. In the state ϕ1, the output current I_{OUT} is supplied to a load via the flywheel diode Di of the lower arm 14 (current source). In the state ϕ1, the output voltage V_{OUT} is set to −Vf. Here, Vf represents the forward voltage of the flywheel diode Di.

In the state ϕ2, the output current I_{OUT} of the bridge circuit 10 flows through the high-side transistor MH. Furthermore, a reverse recovery current Irc flows through the flywheel diode Di of the lower arm 14 from the cathode to the anode. Accordingly, both the output current I_{OUT} and the reverse recovery current Irc flow through the high-side transistor MH. This state is equivalent to through current flowing. In a case in which such through current flows, this leads to an unstable state of the output voltage V_{OUT} of the bridge circuit 10, resulting in the occurrence of ringing. Such ringing is undesired because it becomes a cause of unnecessary radiation.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram of a bridge circuit;

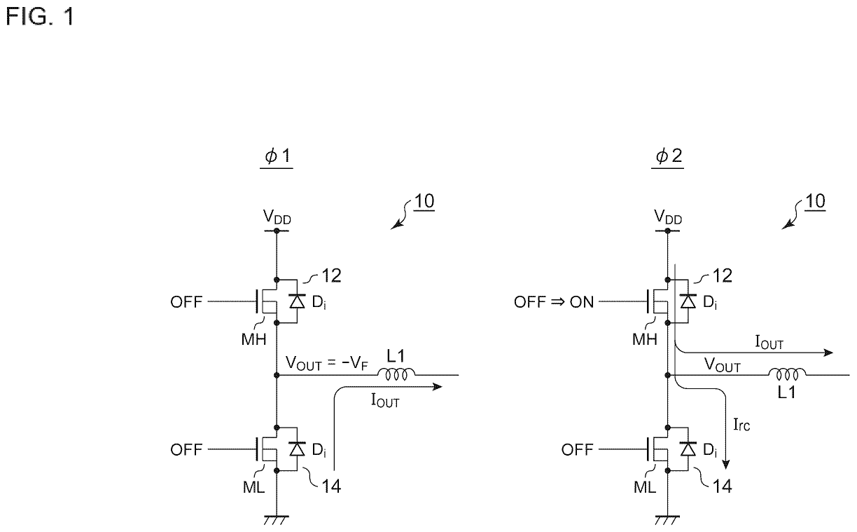

FIG. 2 is a circuit diagram of a switching circuit according to an embodiment;

FIG. 3 is a circuit diagram of a gate driver circuit according to an embodiment;

FIG. 4 is an operation waveform diagram of the gate driver circuit shown in FIG. 3;

FIG. 5 is a circuit diagram of a gate driver circuit according to a modification 1;

FIG. 6 is a circuit diagram of a gate driver circuit according to a modification 2;

FIG. 7 is a circuit diagram of a driving circuit provided with a gate driver circuit;

FIG. 8 is a circuit diagram showing an example configuration of a turn-on circuit;

FIG. 9 is a circuit diagram of a driving circuit; and

FIG. 10 is a circuit diagram of a motor driving apparatus provided with a switching circuit according to an embodiment.

### DETAILED DESCRIPTION

### Outline of Embodiments

An outline of several example embodiments of the disclosure follows. This outline is provided for the convenience of the reader to provide a basic understanding of such embodiments and does not wholly define the breadth of the disclosure. This outline is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “one embodiment” may be used herein to refer to a single embodiment or multiple embodiments of the disclosure.

The outline is by no means a comprehensive outline of all possible embodiments. That is to say, the outline is by no means intended to identify the indispensable or essential elements of all the embodiments and is by no means intended to define the scope of a part of or all the embodiments. The sole purpose of the outline is to present several concepts of one or multiple embodiments in a simple form as a prelude to the detailed description described later.

A gate driver circuit according to one embodiment drives a power transistor that forms a switching circuit. The gate driver circuit includes: a turn-on circuit configured to supply a current as a source to a gate of the power transistor; and a turn-off circuit configured to sink a current from the gate of the power transistor. The turn-on circuit includes: a first current source configured to generate a first current that can be switched between a first current amount and a second current amount that is smaller than the first current amount; a first current mirror circuit having an input node coupled to the first current source and a first output node; a first switch coupled between the first output node of the first current mirror circuit and the gate of the power transistor; a second current source configured to generate a second current; a second current mirror circuit having an input node coupled to the second current source and a first output node; a second switch coupled between the first output node of the second current mirror circuit and the gate of the power transistor; and a control circuit configured to control the first switch, the second switch, the first current source, and the second current source. The control circuit is structured to make a transition to a first period in response to a turn-on instruction for the power transistor, then make a transition to a second period, and then make a transition to a third period, wherein (i) in the first period, the control circuit sets the first current to the first current amount, turns on the first switch, and turns off the second switch, wherein, (ii) in the second period, the control circuit sets the first current to the second current amount, turns on the first switch, and turns off the second switch, and wherein, (iii) in the third period, the control circuit turns off the first switch and turns on the second switch.

With this embodiment, a driving current having the first current amount is supplied to the gate of the power transistor in the first period immediately before the power transistor turns on, so as to raise the gate voltage. Subsequently, in the second period in which a reverse recovery current can flow through the flywheel diode of the lower arm after the power transistor turns on, the driving current to be supplied to the gate of the power transistor is reduced. This gradually turns on the power transistor while maintaining the on resistance of the power transistor at a large value. With this, such an arrangement is capable of suppressing a through current and ringing due to the reverse recovery current that flows through the flywheel diode of the lower arm. Subsequently, in the third period in which there is a low probability that the reverse recovery current will flow, the amount of current supplied to the gate is increased compared to that in the second period. This allows the turn-on time of the power transistor to be shortened, thereby reducing power consumption. Furthermore, the first current mirror circuit operates in each of the first period and the second period. With this, the amount of the input current of the first current mirror circuit is switched. Accordingly, the current supplied to the gate is gradually changed when the first period is switched to the second period. This allows power consumption to be further reduced.

In one embodiment, a current supplied to the gate of the power transistor in the third period may be larger than a current supplied to the gate of the power transistor in the first period and the second period. With such an arrangement in which the amount of current to be supplied to the gate of the power transistor is increased after the effects of the reverse recovery characteristics of the flywheel diode of the lower arm become small, this is capable of reducing the on resistance of the power transistor in a short period of time, thereby providing improved efficiency of the bridge circuit.

In one embodiment, the first current source may include: an output node; a first constant current circuit coupled to the output node; a seventh switch and a second constant current circuit coupled in series between the output node and a ground; and an eighth switch and a third constant current circuit coupled in series between an output of the second constant current circuit and the ground. The current generated by the first constant current circuit is always supplied to the first current mirror circuit. Accordingly, this allows the operating point of the first current mirror circuit at which the first switch turns off to be maintained in the vicinity of the operating point of the operation at which the first switch turns on. With this, such an arrangement is capable of quickly starting the operation of the first current mirror circuit after the first switch is switched from the off state to the on state.

In one embodiment, the second current source may include: an output node; a fourth constant current circuit coupled to the output node; and an eighth switch and a fifth constant current circuit coupled in series between the output node and a ground. The current generated by the fourth constant current circuit is always supplied to the second current mirror circuit. Accordingly, this allows the operating point of the second current mirror circuit at which the second switch turns off to be maintained in the vicinity of the operating point of the operation at which the second switch turns on. With this, such an arrangement is capable of quickly starting the operation of the second current mirror circuit after the second switch is switched from the off state to the on state.

In one embodiment, the turn-on circuit may further include a third switch coupled between the gate of the power transistor and a high-level line where a high voltage that corresponds to a high level of a gate voltage of the power transistor occurs.

In one embodiment, the turn-on circuit may further include a third switch coupled between the first output node of the second current mirror circuit and a high-level line where a high voltage that corresponds to a high level of a gate voltage of the power transistor occurs. With this configuration in which the second switch is configured as a high-breakdown-voltage element, the third switch can be configured as a low-breakdown-voltage element in addition to the second current mirror circuit.

In one embodiment, each of the first current mirror circuit and the second current mirror circuit may further include a second output node. Also, the turn-off circuit may include: a third current mirror circuit having an output node and an input node coupled to the second output node of the first current mirror circuit; a fourth switch coupled between the output node of the third current mirror circuit and the gate of the power transistor; a fourth current mirror circuit having an output node and an input node coupled to the second output node of the second current mirror circuit; and a fifth switch coupled between the output node of the fourth current mirror circuit and the gate of the power transistor. With this configuration, the first current source and the second current source can be shared by the turn-on circuit and the turn-off circuit.

In one embodiment, the turn-off circuit may further include a sixth switch coupled between the gate of the power transistor and a low-level line where a low voltage that corresponds to a low level of a gate voltage of the power transistor occurs.

In one embodiment, the turn-off circuit may further include a sixth switch coupled between the output node of the fourth current mirror circuit and a low-level line where a low voltage that corresponds to a low level of a gate voltage of the power transistor occurs. With this configuration in which the fifth switch is configured as a high-breakdown-voltage element, the sixth switch can be configured as a low-breakdown-voltage element in addition to the fourth current mirror circuit.

In one embodiment, the gate driver circuit may further include a first sensor configured to compare a gate-source voltage of the power transistor with a first threshold voltage. Also, the control circuit may make the transition to the second period in response to a change in an output of the first sensor in the first period. With such an arrangement in which the gate-source voltage of the power transistor is monitored, this is capable of changing the amount of the driving current according to the transition of the power transistor from the off state to the on state. The first threshold voltage may be equal to, or higher than, or lower than the gate threshold value of the MOSFET.

In one embodiment, the first sensor may also be configured to function as a high-side off sensor that detects whether or not the high-side transistor has turned off. This allows the driving current to be reduced before the high-side transistor transits to the on state. In addition, this allows an increase in the circuit area to be suppressed.

In one embodiment, the gate driver circuit may further include a second sensor configured to compare an output voltage of the switching circuit with a second threshold voltage. Also, the control circuit may make the transition to the third period in response to a change in an output of the second sensor in the second period. With such an arrangement in which the output voltage is monitored, this is capable of detecting whether or not the effects of the reverse recovery characteristics of the flywheel diode of the lower arm have become small.

In one embodiment, the gate driver circuit may further include a third sensor configured to compare an output voltage of the switching circuit with a third threshold voltage. Also, the control circuit may make a transition to a fourth period and turns on a third switch in response to a change in an output of the third sensor in the third period.

In one embodiment, the gate driver circuit may monolithically be integrated on a single semiconductor substrate.

A motor driving circuit according to one embodiment includes: a bridge circuit including a high-side transistor and a low-side transistor; a high-side driver configured as any one of the gate driver circuits described above, configured to drive the high-side transistor as the power transistor; and a low-side driver configured as any one of the gate driver circuits described above, configured to drive the low-side transistor as the power transistor.

An electronic device according to one embodiment includes a motor and the motor driving apparatus described above, configured to drive the motor.

### EMBODIMENTS

Description will be made below regarding preferred embodiments with reference to the drawings. The same or similar components, members, and processes are denoted by the same reference numerals, and redundant description thereof will be omitted as appropriate. The embodiments have been described for exemplary purposes only and are by no means intended to restrict the present invention. Also, it is not necessarily essential for the present invention that all the features or a combination thereof be provided as described in the embodiments.

In the present specification, the state represented by the phrase “the member A is coupled to the member B” includes a state in which the member A is indirectly coupled to the member B via another member that does not substantially affect the electrical connection between them, or that does not damage the functions or effects of the connection between them, in addition to a state in which they are physically and directly coupled.

Similarly, the state represented by the phrase “the member C is provided between the member A and the member B” includes a state in which the member A is indirectly coupled to the member C, or the member B is indirectly coupled to the member C, via another member that does not substantially affect the electrical connection between them, or that does not damage the functions or effects of the connection between them, in addition to a state in which they are directly coupled.

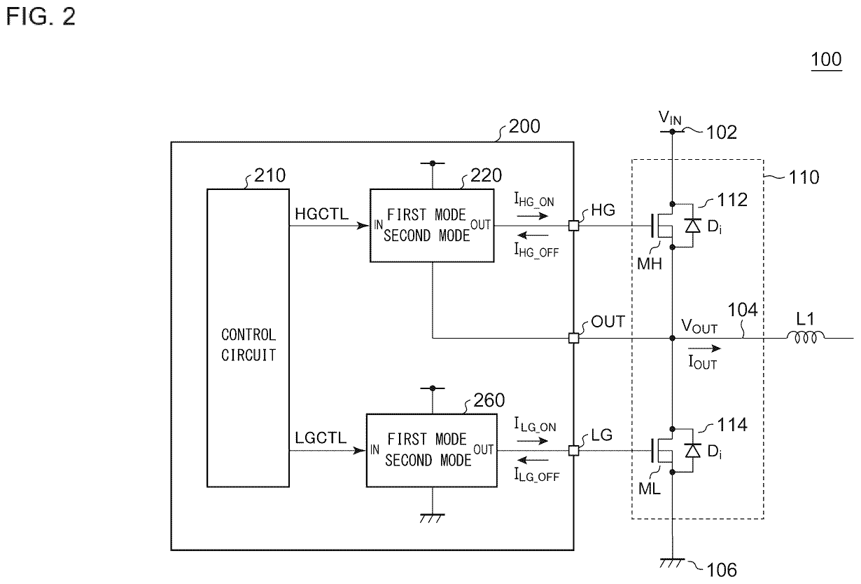

FIG. 2 is a circuit diagram of a switching circuit 100 according to an embodiment. The switching circuit 100 includes a bridge circuit 110 and a driving circuit 200. Although the drawing shows only a configuration of a single leg, the switching circuit 100 may be configured as a three-phase switching circuit or an H-bridge circuit.

The bridge circuit 110 includes an upper arm 112 arranged between a power supply line (input line) 102 and an output terminal (output line) 104 and a lower arm 114 arranged between the output line 104 and a ground line 106. The upper arm 112 includes a high-side transistor MH and a flywheel diode (return current diode) Di coupled in parallel. The lower arm 114 includes a low-side transistor ML and a flywheel diode Di coupled in parallel. In the present embodiment, the high-side transistor MH and the low-side transistor ML are each configured as an N-channel MOSFET with a body diode that functions as the corresponding flywheel diode Di.

The driving circuit 200 controls the upper arm 112 and the lower arm 114 of the bridge circuit 110. The driving circuit 200 switches the state between a high-impedance state ϕ1 in which both the upper arm 112 and the lower arm 114 are turned off, a high-output state ϕ2 in which the upper arm 112 is turned on and the lower arm 114 is turned off, and a low-output state ϕ3 in which the upper arm 112 is turned off and the lower arm 114 is turned on. Description will be made regarding the output current I_{OUT} with the direction of flow toward an inductor L1 that is a load as the positive direction and with the opposite direction as the negative direction. The three states ϕ1 through ϕ3 include states ϕ1A through ϕ3A, respectively, in which the output current I_{OUT} flows in the positive direction (current source). Furthermore, the three states $1 through $3 include states $1B through $3B, respectively, in which the output current I_{OUT} flows in the negative direction (current sink).

The driving circuit 200 includes a control circuit 210, a high-side driver circuit 220, and a low-side driver circuit 260, which are integrated on a single semiconductor substrate so as to form a function IC. The control circuit 210 selects one from among the states ϕ1 through ϕ3 according to the state of the load of the bridge circuit 100 and generates control signals HGCTL and LGCTL that correspond to the state selected from among the states ϕ1 through ϕ3. In the state ϕ1, both the high-side control signal HGCTL and the low-side control signal LGCTL are set to the off level (e.g., low level). In the state ϕ2, the high-side control signal HGCTL is set to the on level (e.g., high level), and the low-side control signal LGCTL is set to the off level. In the state ϕ3, the high-side control signal HGCTL is set to the off level, and the low-side control signal LGCTL is set to the on level.

The high-side driver circuit 220 receives the high-side control signal HGCTL via its input node IN, and its output node OUT is coupled to the gate of the high-side transistor MH via a high-side gate pin HG. When the high-side control signal HGCTL transits from the off level to the on level, the high-side driver circuit 220 supplies a driving current I_{HG_ON} to the gate of the high-side transistor MH. This increases the gate-source voltage Vos of the high-side transistor MH, thereby turning on the high-side transistor MH. Conversely, when the high-side control signal HGCTL transits from the on level to the off level, the high-side driver circuit 220 draws the driving current I_{HG_OFF} from the gate of the high-side transistor MH. This reduces the gate-source voltage V_{GS}, thereby turning off the high-side transistor MH.

The high-side driver circuit 220 is capable of selecting one from among multiple operation modes when the high-side transistor MH is to be turned on, one of which will be referred to as a “first mode”. In the first mode, the high-side driver circuit 220 changes the driving current I_{HG_ON} to be supplied to the gate of the high-side transistor MH in multiple steps according to the state of the bridge circuit 110.

In the first mode, the high-side driver circuit 220 outputs the driving current I_{HG_ON} having a first current amount I₁ during a first period T1 subsequent to the high-side control signal HGCTL transiting from the off level to the on level. Furthermore, the high-side driver circuit 220 outputs the driving current I_{HG_ON} having a second current amount I₂ that is smaller than the first current amount I₁ during a second period T2 subsequent to the first period T1. Furthermore, the high-side driver circuit 220 outputs the driving current I_{HG_ON} having a third current amount I₃ that is larger than the first current amount I₁ and the second current amount I₂ during a third period T3 subsequent to the second period T2.

The high-side driver circuit 220 is configured to support an operation in a second mode in addition to the first mode. In the second mode, the high-side driver circuit 220 generates the driving current I_{HG_ON} having a waveform that differs from that in the first mode. Specifically, in the second mode, the driving current I_{HG_ON} has a constant current amount Ic that is larger than the second current amount I₂ during a period from the transition of the high-side control signal HGCTL from the off level to the on level until the completion of the state transition of the bridge circuit 110. The constant amount Ic may be larger than each of the first current amount I₁ through the third current amount I₃.

The low-side driver circuit 260 receives the low-side control signal LGCTL via its input node IN, and its output node OUT is coupled to the gate of the low-side transistor ML via a low-side gate pin LG. When the low-side control signal LGCTL transits from the off level (e.g., low level) to the on level (high level), the low-side driver circuit 260 supplies the driving current I_{LG_ON} to the gate of the low-side transistor ML so as to increase the gate-source voltage V_{GS} of the low-side transistor ML, thereby turning on the low-side transistor ML. Conversely, when the low-side control signal LGCTL transits from the on level to the off level, the low-side driver circuit 260 draws the driving current I_{LG_OFF} from the gate of the low-side transistor ML. This reduces the gate-source voltage V_{GS}, thereby turning off the low-side transistor ML.

As with the high-side driver circuit 220, the low-side driver circuit 260 is configured to be switchable between the first mode and the second mode.

In the first mode, the low-side driver circuit 260 changes the driving current I_{LG_ON} to be supplied to the gate of the low-side transistor ML in multiple steps according to the state of the bridge circuit 110.

In the first mode, the low-side driver circuit 260 outputs the driving current I_{LG_ON} with a fourth current amount I₄ during a fourth period T4 from the transition of the low-side control signal LGCTL from the off level to the on level. During a fifth period T₅ subsequent to the fourth period T4, the low-side driver circuit 260 outputs the driving current I_{LG_ON} with a fifth current amount I₅ that is smaller than the fourth current amount I₄. Subsequently, during a sixth period T₆ subsequent to the fifth period T₅, the low-side driver circuit 260 outputs the driving current I_{LG_ON} with a sixth current amount I₆ that is larger than the fourth current amount I₄ and the fifth current amount I₅.

In the second mode, the low-side driver circuit 260 generates the driving current I_{LG_ON} having a waveform that differs from that in the first mode. Specifically, in the second mode, during a period from the transition of the low-side control signal LGCTL from the off level to the on level until the completion of the state transition of the bridge circuit 110, the driving current I_{LG_ON} has a constant amount Id that is larger than the fifth current amount I₅. The constant amount Id may be larger than each of the fourth current amount I₄ through the sixth current amount I₆.

The above is the configuration of the switching circuit 100. Next, description will be made regarding the operation thereof.

First, description will be made regarding the operation of the high-side driver circuit 220. In a situation in which a reverse recovery current of the flywheel diode of the lower arm 114 has the potential to occur, the high-side driver circuit 220 operates in the first mode. Conversely, in a situation in which a reverse recovery current of the flywheel diode has no potential to occur, the high-side driver circuit 220 operates in the second mode.

Specifically, the high-side driver circuit 220 operates in the first mode in a situation (source-rise situation) in which the high-side transistor MH is to be turned on in the state ϕ1A in which the high-side transistor MH and the low-side transistor ML are each turned off, and the current I_{OUT} is supplied as a source current via the flywheel diode Di of the lower arm 114.

Furthermore, the high-side driver circuit 220 operates in the second mode in a situation (sink-rise situation) in which the high-side transistor MH is to be turned on in the state in which the high-side transistor MH is turned off and the low-side transistor ML is turned on, and the current I_{OUT} is sunk via the low-side transistor ML.

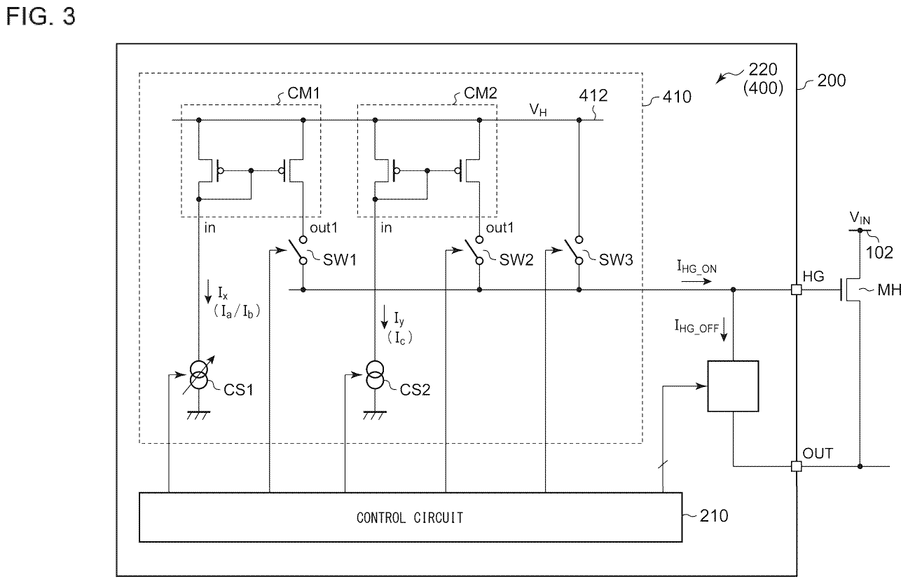

FIG. 3 is a circuit diagram of a gate driver circuit 400 according to an embodiment. In this example, as the gate driver circuit 400, the high-side driver circuit 220 shown in FIG. 2 is employed. The gate driver circuit 400 drives a high-side transistor MH.

A turn-on circuit 410 is configured to supply an on-current I_{HG_ON} as a current source to the gate of the high-side transistor MH configured as a power transistor. A turn-off circuit 420 is configured to sink a current I_{HG_OFF} from the gate of the high-side transistor MH.

The turn-on circuit 410 includes a first current source CS1, a second current source CS2, a first current mirror circuit CM1, a second current mirror circuit CM2, a first switch SW1, a second switch SW2, and a third switch SW3.

The first current source CS1 outputs a first current Ix in the on state. The first current source CS1 is configured to be capable of switching the current amount of the first current Ix between a first current amount Ia and a second current amount Ib that is smaller than the first current amount Ia.

In the off state, the first current source CS1 may set the first current Ix to be completely zero. Preferably, in the off state, the first current source CS1 is configured to output a very small current amount Ic.

The first current mirror circuit CM1 has an input node coupled to the first current source CS1. The first current mirror circuit CM1 mirrors the first current Ix, and outputs the mirrored current via a first output node out1. The first switch SW1 is provided between the first output node out1 of the first current mirror circuit CM1 and the gate of the high-side transistor MH (i.e., high-side gate pin HG).

In the on state, the second current source CS2 outputs a second current Iy with a current amount Ic. The second current mirror circuit CM2 has an input node coupled to the second current source CS2. The second current mirror circuit CM2 mirrors the second current Iy, and outputs the mirrored current via the first output node out1. The second switch SW2 is provided between the first output node out1 of the second current mirror circuit CM2 and the gate of the high-side transistor MH (i.e., high-side gate pin HG).

In the off state, the second current source CS2 may set the second current Iy to be completely zero. Preferably, in the off state, the second current source CS2 is configured to output a very small current amount Id.

The third switch SW3 is coupled between the gate of the high-side transistor MH and a high-level line 412 where a high voltage V_{H} that corresponds to the high level of the gate voltage of the high-side transistor MH occurs. The high voltage V_{H} may be a bootstrap voltage generated by a bootstrap circuit. Also, the high voltage V_{H} may be generated by a charge pump circuit.

The control circuit 210 generates the control signal HGCTL, which is an instruction for the states of the turn-on circuit 410 and the turn-off circuit 420. Specifically, the control circuit 210 is configured to control the first current source CS1, the second current source CS2, the first switch SW1, the second switch SW2, and the third switch SW3 with respect to the turn-on circuit 410.

In a first mode, the control circuit 210 operates according to a sequence described below in response to a turn-on instruction for the high-side transistor MH.

### (i) First Period T1

Description will be made assuming that the first current source CS1 is turned on and the second current source CS2 is turned off. The first current source CS1 generates a first current Ix with a first current amount Ia. Furthermore, the first switch SW1 is turned on, and the second switch SW2 and the third switch SW3 are each turned off.

In the first period T1, the current I_{HG_ON} having a first current amount I₁ is supplied to the gate of the high-side transistor MH. With the mirror ratio of the first current mirror circuit CM1 as α, the first current amount I₁ is represented by the following Expression.

$${I}_{1} = I a \times α .$$

### (ii) Second Period T2

The first current Ix is reduced to the second current amount Ib while the first current source CS1 is maintained in the on state. The states of the first switch SW1, the second switch SW2, the third switch SW3, and the second current source CS2 are each maintained.

In the second period T2, the current I_{HG_ON} having a second current amount I₂ is supplied to the gate of the high-side transistor MH. The second current amount I2 is represented by the following Expression.

$${I}_{2} = I b \times α .$$

Here, Ib<Ia, and accordingly, I₂<I₁.

### (iii) Third Period T3

In the third period T3, the first current source CS1 is turned off, and the second current source CS2 is turned on. In this period, the second switch SW2 is turned on, and the first switch SW1 is turned off.

In the third period T3, the current I_{HG_ON} having a third current amount I₃ is supplied to the gate of the high-side transistor MH. With the mirror ratio of the second current mirror circuit CM2 as β, the third current amount I₃ is represented by the following Expression.

$${I}_{3} = I c \times β .$$

Here, Ic and B are determined such that I₃>I₁.

### (iv) Fourth Period T4

The first current source CS1 and the second current source CS2 are each turned off. Furthermore, the first switch SW1 and the second switch S2 are each turned off, and the third switch SW3 is turned on.

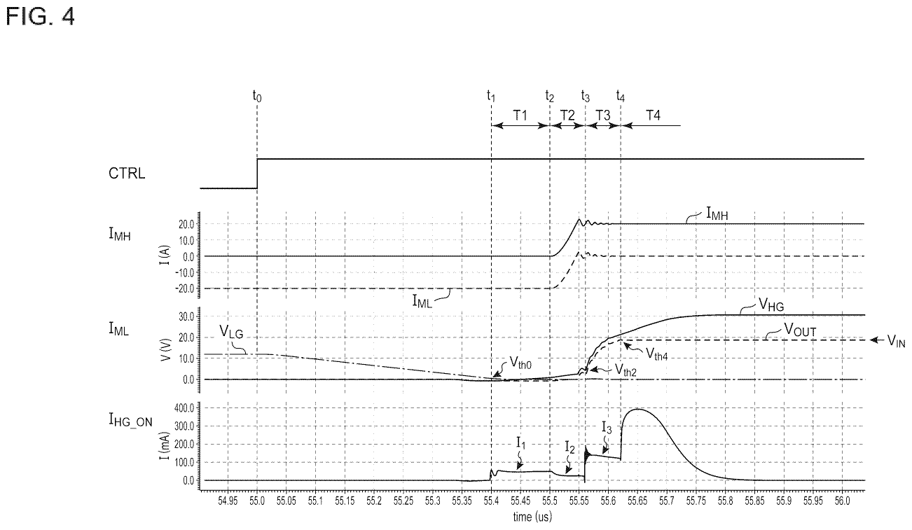

FIG. 4 is an operation waveform diagram of the gate driver circuit 400 shown in FIG. 3. A control signal CTRL is a logic signal that functions as an instruction to control the state of the bridge circuit 110. A current I_{MH} represents a current that flows through the high-side transistor MH. A current I_{ML} represents a current that flows through the low-side transistor ML. The direction of current flow from the drain toward the source will be taken to be positive. V_{LG} represents the gate voltage (gate-source voltage) of the low-side transistor ML. V_{HG} represents the gate voltage of the high-side transistor MH. V_{OUT} represents the output voltage. The electric potential difference between V_{HG} and V_{OUT} is the gate-source voltage of the high-side transistor MH.

Before the time point to, the control signal CTRL is set to the low level. In this period, the high-side transistor MH is turned off, and the low-side transistor ML is turned on, thereby outputting the output voltage V_{OUT} having a low voltage (0 V).

FIG. 4 shows the operation in a current source mode. In this mode, before the time point to, a negative current I_{ML} flows through the low-side transistor ML.

At the time point to, the control signal CTRL transits to the high level. With this, the low-side driver circuit 260 reduces the gate voltage V_{LG} of the low-side transistor ML, thereby turning off the low-side transistor ML.

When the gate voltage V_{LG} of the low-side transistor ML becomes lower than a fourth threshold voltage Vth4 at the time point t1, the high-side driver circuit 220 becomes active. In the first period T1, the turn-on circuit 410 supplies the current I_{HG_ON} having the first current amount I₁ to the gate of the high-side transistor MH.

Subsequently, when the gate-source voltage (V_{HG}−V_{OUT}) of the high-side transistor MH exceeds a first threshold voltage Vth1 at the time point t₂, the period transits to the second period T2. In the second period T2, the turn-on circuit 410 supplies the current I_{HG_ON} having the second current amount I₂ to the gate of the high-side transistor MH. The second current amount I₂ is smaller than the first current amount I₁.

Subsequently, when the output voltage V_{OUT} exceeds a second threshold voltage Vth2 at the time point t₃, the period transits to the third period T3. In the third period T3, the turn-on circuit 410 supplies the current I_{HG_ON} having the third current amount I₃ to the gate of the high-side transistor MH. The third current amount I₃ is larger than the first current amount I₁ and the second current amount I₂.

Subsequently, when the output voltage V_{OUT} exceeds a third threshold voltage Vth3 set in the vicinity of the input voltage V_{IN} at the time point t4, the period transits to the fourth period T4. In this period, the third switch SW3 is turned on. When the third switch SW3 is turned on, the gate voltage V_{HG} of the high-side transistor MH is fixed to a high-level voltage, thereby strongly fixing the high-side transistor MH to the on state.

The above is the operation of the switching circuit 100.

With the switching circuit 100, a period immediately before the turn-on of the high-side transistor MH is defined as the first period T1. In this period, the driving current I_{HG_ON} having the first current amount I₁ is supplied to the gate of the high-side transistor MH, thereby raising the gate voltage V_{HG}. Subsequently, during the second period T2 in which a reverse recovery current can flow through the flywheel diode of the lower arm after the turn-on of the high-side transistor MH, the driving current I_{HG_ON} to be supplied to the gate of the high-side transistor MH is reduced to the second current amount I₂. This allows the high-side transistor MH to gradually turn on while maintaining a high on resistance of the high-side transistor MH. This is capable of suppressing a through current and ringing due to the reverse recovery current that flows through the flywheel diode of the lower arm.

Subsequently, in the third period T3 in which there is a low probability that the reverse recovery current will flow, the driving current I_{HG_ON} to be supplied to the gate of the high-side transistor MH is increased to the third current amount I₃ that is larger than that in the second period T2. This allows the turn-on time of the high-side transistor MH to be shortened, thereby reducing power consumption.

Furthermore, in the first period T1 and the second period T2, the first current mirror circuit CM1 operates with the input current Ix of the first current mirror circuit CM1 being changed. Accordingly, when the period is switched from the first period T1 to the second period T2, the driving current I_{HG_ON} gradually changes from the first current amount I₁ toward the second current amount I₂. This allows power consumption to be further reduced.

Furthermore, in the third period T3, the driving current I_{HG_ON} supplied to the gate of the high-side transistor MH is larger than the first current amount I₁ in the first period T1. This allows the on resistance of the high-side transistor MH to be reduced in a short period of time, thereby further improving the efficiency of the bridge circuit.

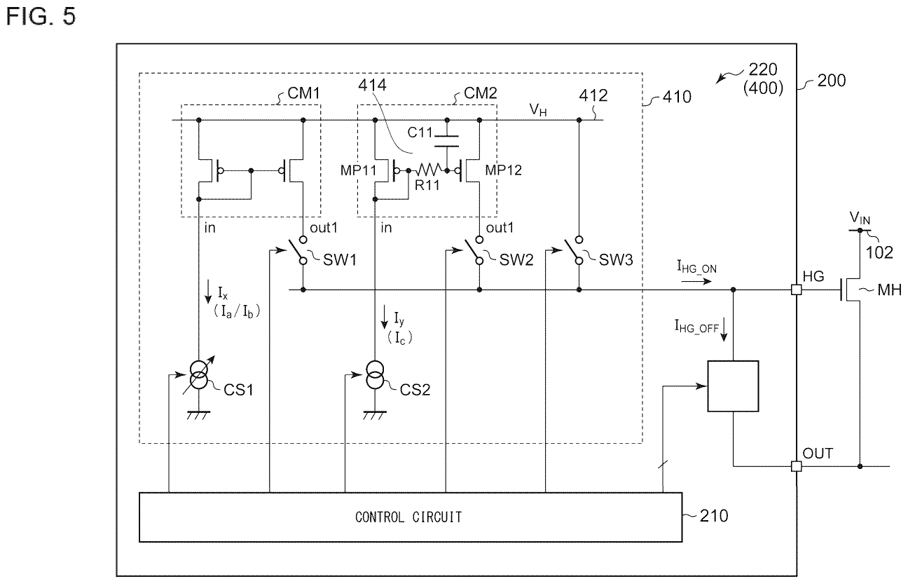

FIG. 5 is a circuit diagram of the gate driver circuit 400 according to a modification 1. In this modification, the second current mirror circuit CM2 includes a low-pass filter 414 between the PMOS transistor MP11 on the input side and the PMOS transistor MP12 on the output side. The low-pass filter 414 is configured as an RC filter including a resistor R11 and a capacitor C11. With such a low-pass filter, this provides an effect of stabilizing a current that flows through the second current mirror circuit CM2 even if the high voltage V_{H} fluctuates in the PWM driving operation.

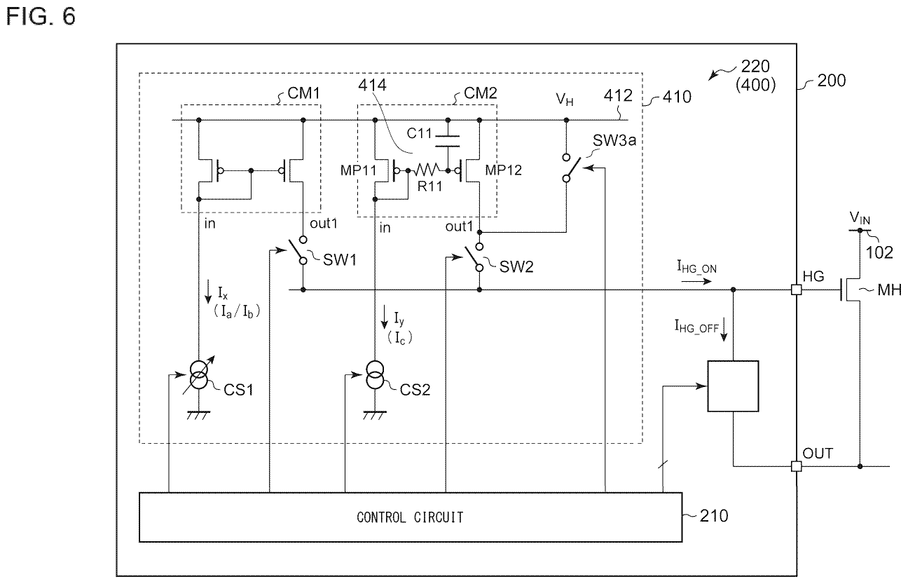

FIG. 6 is a circuit diagram of the gate driver circuit 400 according to a modification 2. As compared with the gate driver circuit 400 shown in FIG. 5, the gate driver circuit 400 shown in FIG. 6 has a configuration with a third switch SW3 at a different position. Specifically, the third switch SW3a is coupled between the high-level line 412 and the first output node out1 of the second current mirror circuit CM2.

Description will be made regarding advantages of the modification shown in FIG. 6. In the configuration shown in FIG. 3, in a case of employing an application having a large voltage difference between the high-level line 412 and the high-side gate pin HG, the second switch SW2 and the third switch SW3 are each required to be configured as a high-breakdown-voltage element having a large area. In contrast, with the modification shown in FIG. 6, only the second switch SW2 is preferably configured as a high-breakdown-voltage element. This allows the third switch SW3a to be configured as a low-breakdown-voltage element. Accordingly, this allows the circuit area to be reduced.

It should be noted that, in the gate driver circuit 400 shown in FIG. 3, instead of the third switch SW3, a third switch SW3a configured as a low-breakdown-voltage element may be provided.

Next, description will be made regarding an example configuration of the turn-off circuit 420.

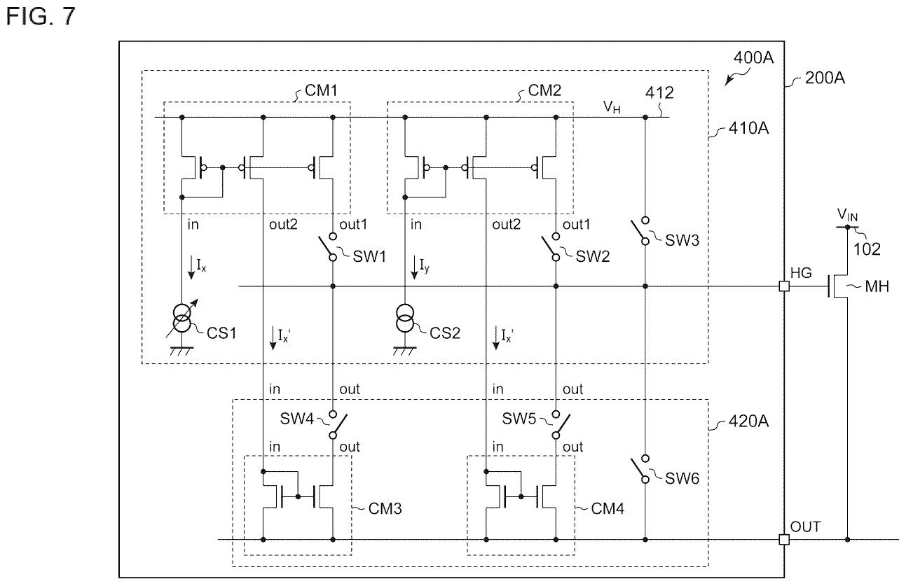

FIG. 7 is a circuit diagram of a driving circuit 200A including a gate driver circuit 400A. The gate driver circuit 400A includes a turn-on circuit 410A and a turn-off circuit 420A.

The turn-on circuit 410A has the same basic configuration as that shown in FIG. 3. The turn-on circuit 410A includes a first current source CS1, a second current source CS2, a first current mirror circuit CM1, a second current mirror circuit CM2, a first switch SW1, a second switch SW2, and a third switch SW3.

The first current mirror circuit CM1 and the second current mirror circuit CM2 each include a second output node out2. The first current mirror circuit CM1 mirrors a current Ix, and supplies a current Ix′ to the turn-off circuit 420A. The second current mirror circuit CM2 mirrors a current Iy and supplies a current Iy′ to the turn-off circuit 420A.

The turn-off circuit 420A includes a third current mirror circuit CM3, a fourth current mirror circuit CM4, a fourth switch SW4, a fifth switch SW5, and a sixth switch SW6.

The input node in of the third current mirror circuit CM3 is coupled to the second output node out2 of the first current mirror circuit CM1. The third current mirror circuit CM3 mirrors the current Ix′. The fourth switch SW4 is provided between the output node out of the third current mirror circuit CM3 and the gate of the high-side transistor MH.

The input node in of the fourth current mirror circuit CM4 is coupled to the second output node out2 of the second current mirror circuit CM2. The fourth current mirror circuit CM4 mirrors the current Iy′. The fifth switch SW5 is provided between the output node out of the fourth current mirror circuit CM4 and the gate of the high-side transistor MH.

The sixth switch SW6 is coupled between the gate and the source of the high-side transistor MH.

The fourth switch SW4 through the sixth switch SW6 of the turn-off circuit 420 are each controlled according to the control signal HGCTL generated by the control circuit 210.

With the turn-off circuit 420A, when the high-side transistor MH is to be turned off, this is capable of changing the driving current I_{HG_OFF} generated by the turn-off circuit 420 in a stepwise manner in the same manner as the driving current I_{HG_ON} to be used in the turn-on operation.

Next, description will be made regarding a more specific example configuration of the turn-on circuit 410.

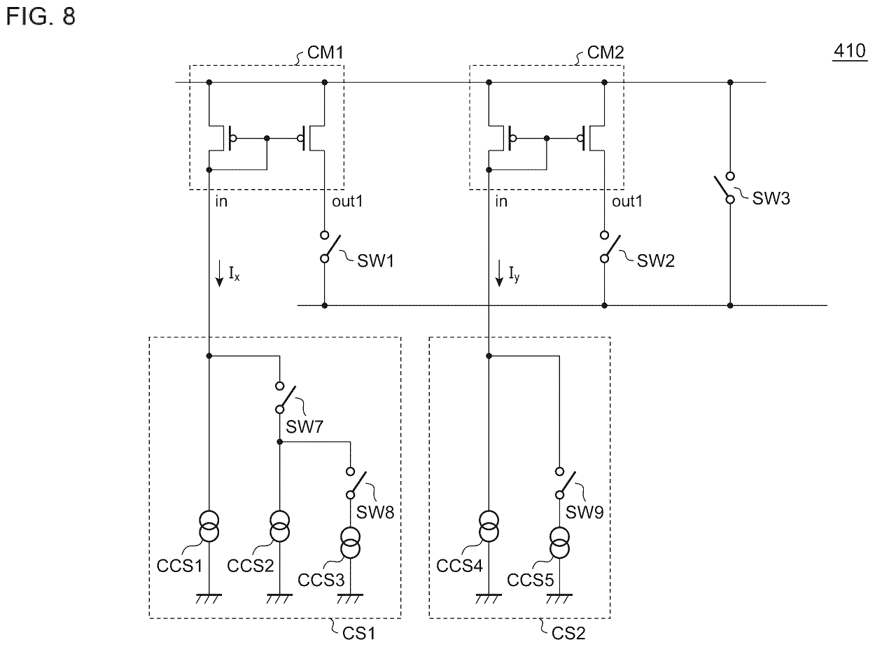

FIG. 8 is a circuit diagram showing an example configuration of the turn-on circuit 410. The first current source CS1 includes a first constant current circuit CCS1, a second constant current circuit CCS2, a third constant current circuit CCS3, a seventh switch SW7, and an eighth switch SW8.

The first constant current circuit CCS1 is coupled to the output node of the first current source CS1. The seventh switch SW7 and the second constant current circuit CCS2 are coupled in series between the output node and the ground. The eighth switch SW8 and the third constant current circuit CCS3 are coupled in series between the output of the second constant current circuit CCS2 and the ground.

In the off state, the first current source CS1 operates with the seventh switch SW7 turned off. In the on state, in the first period T1, the first current source CS1 operates with the seventh switch SW7 and the eighth switch SW8 turned on. In the second period T2, the seventh switch SW7 is turned on, and the eighth switch SW8 is turned off.

In the off state, the first current source CS1 continues to output the output current of the first constant current circuit CCS1 as a current Ix having a very small current amount. This is capable of suppressing fluctuation of the operating point of the first current mirror circuit CM1, thereby allowing the operating speed of the second current mirror circuit CM2 to be raised. This provides the turn-on circuit 410 with improved responsiveness.

The second current source CS2 includes a fourth constant current circuit CCS4, a fifth constant current circuit CCS5, and a ninth switch SW9. The fourth constant current circuit CCS4 is coupled to the output node of the second current source CS2. The ninth switch SW9 and the fifth constant current circuit CCS5 are coupled in series between the output node of the second current source CS2 and the ground.

In the off state of the second current source CS2, the ninth switch SW9 is turned off. In the on state, the ninth switch SW9 is turned on.

Furthermore, in the off state, the second current source CS2 continues to output the output current of the fourth constant current circuit CCS4 as a current Iy having a very small current amount. This is capable of suppressing fluctuation of the operating point of the second current mirror circuit CM2, thereby allowing the operating speed of the second current mirror circuit CM2 to be raised. This provides the turn-on circuit 410 with improved responsiveness.

In FIGS. 7 and 8, the second current mirror circuit CM2 may further include a low-pass filter 414 described with reference to FIG. 5 (modification 1) as an additional component. Also, the third switch SW3 may be replaced by the third switch SW3a described with reference to FIG. 6 (modification 2).

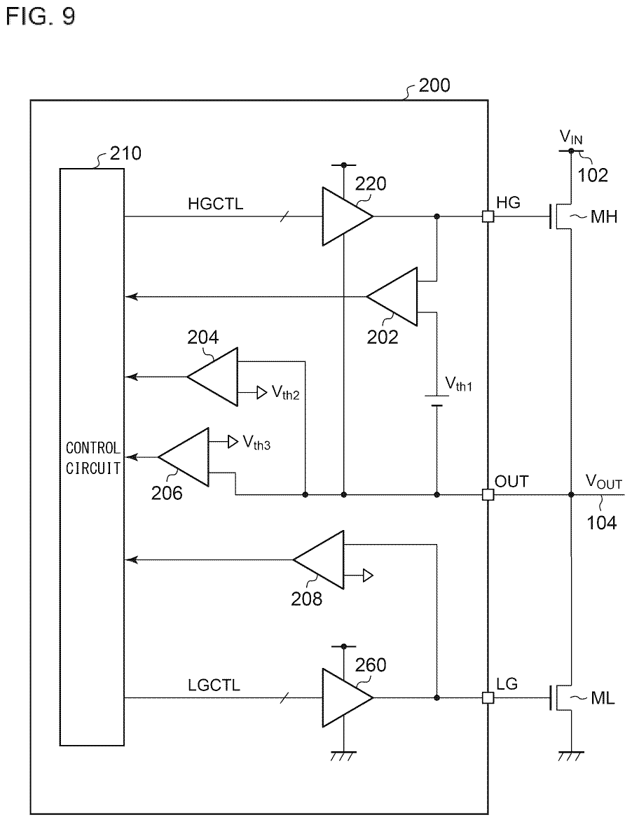

FIG. 9 is a circuit diagram of the driving circuit 200. The driving circuit 200 may include a first sensor 202, a second sensor 204, a third sensor 206, and a low-side off sensor 208.

The low-side off sensor 208 detects the turn-off of the low-side transistor ML. The low-side off sensor 208 compares the gate-source voltage of the low-side transistor ML with the fourth threshold voltage Vth4. Upon detecting the turn-off of the low-side transistor ML based on the output of the low-side off sensor 208, the control circuit 210 transits to the first period T1.

The first sensor 202 compares the gate-source voltage V_{GS} of the high-side transistor MH with a first threshold voltage Vₜₕ₁. The first threshold voltage Vₜₕ₁ may preferably be determined based on the threshold voltage V_{GS(th)} of the MOSFET.

In many cases, the driving circuit 200 is provided with a high-side off sensor that detects whether or not the high-side transistor MH turns off. The output of the high-side off sensor is referenced by the control circuit 210. The control circuit 210 monitors the output of the high-side off sensor. After the high-side transistor MH turns off completely, the control circuit 210 switches the low-side control signal LGCTL to the on level. This is capable of preventing the high-side transistor MH and the low-side transistor ML from turning on at the same time, thereby preventing the occurrence of through current.

In a case in which the driving circuit 200 is provided with such a high-side off sensor, the first sensor 202 can be shared by the high-side off sensor. This allows the circuit area to be reduced.

When the output of the first sensor 202 changes, i.e., the gate-source voltage V_{GS} of the high-side transistor MH exceeds the first threshold voltage Vₜₕ₁, in the first period T1, the high-side driver circuit 220 transits to the second period T2. In a case in which the first threshold voltage Vₜₕ₁ is set to a value that is lower than the threshold voltage V_{GS(th)} of the MOSFET, such an arrangement allows the high-side driver circuit 220 to transit to the second period T2 before the turn-on of the high-side transistor MH. In a case in which the high-side driver circuit 220 has a large response delay, the high-side driver circuit 220 transits to the second period T2 at the same time as the turn-on or with a slight delay after the turn-on.

With such an arrangement in which the gate-source voltage V_{GS} of the high-side transistor MH is monitored, such an arrangement is capable of changing the amount of the driving current I_{HG_ON} according to the transition of the high-side transistor MH from the off state to the on state.

The second sensor 204 compares the output voltage V_{OUT} of the output line 104 with the second threshold voltage V_{Tth2}. In the second period T2, the high-side driver circuit 220 transits to the third period T3 in response to the change in output of the second sensor 204. With such an arrangement in which the output voltage V_{OUT} is monitored, such an arrangement is capable of detecting a reduction in the effects of the reverse recovery characteristics of the flywheel diode Di of the lower arm 114.

In some cases, the driving circuit 200 is provided with a sensor (voltage monitoring circuit) that compares the output voltage V_{OUT} with a threshold voltage that is a predetermined voltage width lower than the input voltage V_{IN} in order to detect whether or not the output voltage V_{OUT} completely transits from the low level to the high level, or for other purposes. In this case, the voltage monitoring circuit is also configured as the second sensor 204, thereby suppressing an increase in the circuit area.

The third sensor 206 compares the output voltage V_{OUT} with a third threshold voltage Vth3 determined in the vicinity of the input voltage VIN. The control circuit 210 refers to the output of the third sensor 206, and when V_{OUT} exceeds Vth3, the control circuit 210 transits to the fourth period T4.

Next, description will be made regarding the configuration and the operation of the low-side driver circuit 260. The low-side driver circuit 260 may be configured in the same manner as the high-side driver circuit 220.

In a situation in which a reverse recovery current can occur in the flywheel diode of the upper arm 112, the low-side driver circuit 260 operates in the first mode. In a situation in which the reverse recovery current cannot occur, the low-side driver circuit 260 operates in the second mode.

Specifically, in a situation (sink fall) in which both the high-side transistor MH and the low-side transistor ML are off and the low-side transistor ML is to be turned on in a state $1B in which the output I_{OUT} is sunk via the flywheel diode Di of the upper arm 112, the low-side driver circuit 260 operates in the first mode.

On the other hand, in a situation (source fall) in which the high-side transistor MH is on and the low-side transistor ML is off and the low-side transistor ML is to be turned on in a state in which the output I_{OUT} is supplied as a source current via the high-side transistor MH, the low-side driver circuit 260 operates in the second mode.

Next, description will be made regarding the usage of the switching circuit 100. The switching circuit 100 can preferably be employed in a driving circuit of a motor.

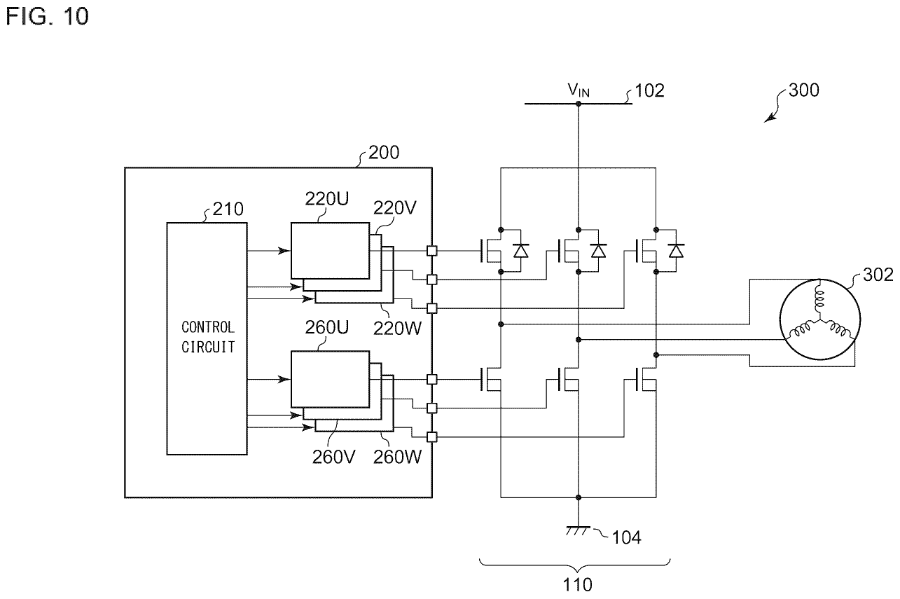

FIG. 10 is a circuit diagram of a motor driving apparatus 300 provided with the switching circuit 100 according to an embodiment. The motor driving apparatus 300 drives a three-phase motor 302 configured as a load, and controls the rotational state thereof.

The motor driving apparatus 300 includes a bridge circuit 110 and a driving circuit 200. The bridge circuit 110 is configured as a three-phase inverter including a U-phase leg, V-phase leg, and W-phase leg. Each phase leg includes an upper arm and a lower arm.

The driving circuit 200 includes a control circuit 210 and high-side driver circuits 220U through 220W, and low-side driver circuits 260U through 260W. The control circuit 210 generates control signals that indicate the states of the six arms that form the bridge circuit 110 based on the state of the three-phase motor 302 configured as a load.

The high-side driver circuits 220U through 220W are each configured to have the architecture of the high-side driver circuit 220 described above. Furthermore, the low-side driver circuits 260U through 260W are each configured to have the architecture of the low-side driver circuit 260 described above.

Description has been made above regarding the three-phase motor as an example. Also, the present invention is applicable to a single-phase motor. In this case, the bridge circuit 110 is configured as an H-bridge circuit.

Next, description will be made regarding the usage of the motor driving apparatus 300. The motor driving apparatus 300 can be used to control a spindle motor of a hard disk, and to control a lens driving motor of an imaging device. Also, the motor driving apparatus 300 can be used to drive a printer head driving motor and to drive a sheet-feeding motor. Also, the motor driving apparatus 300 can be employed to drive a motor of an electric vehicle, hybrid vehicle, etc.

The embodiments have been described for exemplary purposes only. Rather, it can be readily conceived by those skilled in this art that various modifications may be made by making various combinations of the aforementioned components or processes, which are also encompassed in the technical scope of the present disclosure or the present invention. Description will be made below regarding such modifications.

### Modification 1

Description has been made in the embodiment regarding an arrangement in which the bridge circuit 110 is formed of discrete components. However, the present invention is not restricted to such an arrangement. Also, the bridge circuit 110 may be integrated on the driving circuit 200.

### Modification 2

The upper arm 112 and the lower arm 114 may each be formed of an Insulated Gate Bipolar Transistor (IGBT).

### Modification 3

Description has been made in the embodiment regarding an arrangement in which both the high-side driver circuit 220 and the low-side driver circuit 260 are each configured to be capable of selecting one from among multiple modes. Also, only one of the high-side driver circuit 220 and the low-side driver circuit 260 may be configured to be capable of controlling the mode.

### Modification 4

The usage of the switching circuit 100 is not restricted to the motor driving apparatus 300. For example, the switching circuit 100 is suitably employed for switching regulators (DC/DC converters), various kinds of power conversion apparatuses (inverters or converters), lighting inverters for discharge lamps, digital audio amplifiers, etc. Accordingly, the switching circuit 100 is applicable to consumer devices including electronic devices and consumer electronics devices, automobiles, in-vehicle components, industrial vehicles, and industrial equipment.

The embodiments described using specific terms show only the mechanisms and applications of the present disclosure. Rather, various modifications and various changes in the layout can be made without departing from the spirit and scope of the present disclosure defined in appended claims.

### Notes

The following techniques are disclosed in the present specification.

### Item 1

A gate driver circuit structured to drive a power transistor that forms a switching circuit, the gate driver circuit including: a turn-on circuit structured to supply a current as a source to a gate of the power transistor; a turn-off circuit structured to sink a current from the gate of the power transistor; and a control circuit structured to control the turn-on circuit and the turn-off circuit, wherein the turn-on circuit includes: a first current source structured to generate a first current that can be switched between a first current amount and a second current amount that is smaller than the first current amount; a first current mirror circuit having an input node coupled to the first current source and a first output node; a first switch coupled between the first output node of the first current mirror circuit and the gate of the power transistor; a second current source structured to generate a second current; a second current mirror circuit having an input node coupled to the second current source and a first output node; and a second switch coupled between the first output node of the second current mirror circuit and the gate of the power transistor, wherein the control circuit is structured to control the first switch, the second switch, the first current source, and the second current source, wherein the control circuit is structured to make a transition to a first period in response to a turn-on instruction for the power transistor, then make a transition to a second period, and then make a transition to a third period, wherein, (i) in the first period, the control circuit sets the first current to the first current amount, turns on the first switch, and turns off the second switch, wherein, (ii) in the second period, the control circuit sets the first current to the second current amount, turns on the first switch, and turns off the second switch, and wherein, (iii) in the third period, the control circuit turns off the first switch and turns on the second switch.

### Item 2

The gate driver circuit according to item 1, wherein a current supplied to the gate of the power transistor in the third period is larger than a current supplied to the gate of the power transistor in the first period and the second period.

### Item 3

The gate driver circuit according to item 1 or 2, wherein the turn-on circuit further includes a third switch coupled between the gate of the power transistor and a high-level line where a high voltage that corresponds to a high level of a gate voltage of the power transistor occurs.

### Item 4

The gate driver circuit according to item 1 or 2, wherein the turn-on circuit further includes a third switch coupled between the first output node of the second current mirror circuit and a high-level line where a high voltage that corresponds to a high level of a gate voltage of the power transistor occurs.

### Item 5

The gate driver circuit according to any one of items 1 through 4, wherein each of the first current mirror circuit and the second current mirror circuit further includes a second output node,
wherein the turn-off circuit includes:
   a third current mirror circuit having an output node and an input node coupled to the second output node of the first current mirror circuit;
   a fourth switch coupled between the output node of the third current mirror circuit and the gate of the power transistor;
   a fourth current mirror circuit having an output node and an input node coupled to the second output node of the second current mirror circuit; and
   a fifth switch coupled between the output node of the fourth current mirror circuit and the gate of the power transistor.

### Item 6

The gate driver circuit according to any one of items 1 through 5, wherein the turn-off circuit further includes a sixth switch coupled between the gate of the power transistor and a low-level line where a low voltage that corresponds to a low level of a gate voltage of the power transistor occurs.

### Item 7

The gate driver circuit according to item 5, wherein the turn-off circuit further includes a sixth switch coupled between the output node of the fourth current mirror circuit and a low-level line where a low voltage that corresponds to a low level of a gate voltage of the power transistor occurs.

### Item 8

The gate driver circuit according to any one of items 1 through 7, wherein the first current source includes:
an output node;
a first constant current circuit coupled to the output node;
a seventh switch and a second constant current circuit coupled in series between the output node and a ground; and
an eighth switch and a third constant current circuit coupled in series between an output of the second constant current circuit and the ground.

### Item 9

The gate driver circuit according to any one of items 1 through 8, wherein the second current source includes:
an output node;
a fourth constant current circuit coupled to the output node; and
a ninth switch and a fifth constant current circuit coupled in series between the output node and a ground.

### Item 10

The gate driver circuit according to any one of items 1 through 9, further including a first sensor structured to compare a gate-source voltage of the power transistor with a first threshold voltage,
wherein the control circuit makes the transition to the second period in response to a change in an output of the first sensor in the first period.

### Item 11

The gate driver circuit according to any one of items 1 through 10, further including a second sensor structured to compare an output voltage of the switching circuit with a second threshold voltage,
wherein the control circuit makes the transition to the third period in response to a change in an output of the second sensor in the second period.

### Item 12

The gate driver circuit according to item 3 or 4, further including a third sensor structured to compare an output voltage of the switching circuit with a third threshold voltage,
wherein the control circuit makes a transition to a fourth period and turns on a third switch in response to a change in an output of the third sensor in the third period.

### Item 13

The gate driver circuit according to any one of items 1 through 12, monolithically integrated on a single semiconductor substrate.

### Item 14

A motor driving apparatus including:
a bridge circuit including a high-side transistor and a low-side transistor;
a high-side driver structured as the gate driver circuit according to any one of items 1 through 13, structured to drive the high-side transistor as the power transistor; and
a low-side driver structured as the gate driver circuit according to any one of items 1 through 13, structured to drive the low-side transistor as the power transistor.

### Item 15

An electronic device including:
a motor; and
the motor driving apparatus according to item 14, structured to drive the motor.

What is claimed is:

1. A gate driver circuit structured to drive a power transistor that forms a switching circuit, the gate driver circuit comprising:
a turn-on circuit structured to supply a current as a source to a gate of the power transistor;
a turn-off circuit structured to sink a current from the gate of the power transistor; and
a control circuit structured to control the turn-on circuit and the turn-off circuit,
wherein the turn-on circuit comprises:
a first current source structured to generate a first current that can be switched between a first current amount and a second current amount that is smaller than the first current amount;
a first current mirror circuit having an input node coupled to the first current source and a first output node;
a first switch coupled between the first output node of the first current mirror circuit and the gate of the power transistor;
a second current source structured to generate a second current;
a second current mirror circuit having an input node coupled to the second current source and a first output node; and
a second switch coupled between the first output node of the second current mirror circuit and the gate of the power transistor,
wherein the control circuit is structured to control the first switch, the second switch, the first current source, and the second current source,
wherein the control circuit is structured to make a transition to a first period in response to a turn-on instruction for the power transistor, then make a transition to a second period, and then make a transition to a third period,
wherein, (i) in the first period, the control circuit sets the first current to the first current amount, turns on the first switch, and turns off the second switch,
wherein, (ii) in the second period, the control circuit sets the first current to the second current amount, turns on the first switch, and turns off the second switch,
and wherein, (iii) in the third period, the control circuit turns off the first switch and turns on the second switch.

2. The gate driver circuit according to claim 1, wherein a current supplied to the gate of the power transistor in the third period is larger than a current supplied to the gate of the power transistor in the first period and the second period.

3. The gate driver circuit according to claim 1, wherein the turn-on circuit further comprises a third switch coupled between the gate of the power transistor and a high-level line where a high voltage that corresponds to a high level of a gate voltage of the power transistor occurs.

4. The gate driver circuit according to claim 1, wherein the turn-on circuit further comprises a third switch coupled between the first output node of the second current mirror circuit and a high-level line where a high voltage that corresponds to a high level of a gate voltage of the power transistor occurs.

5. The gate driver circuit according to claim 1, wherein each of the first current mirror circuit and the second current mirror circuit further comprises a second output node,
wherein the turn-off circuit comprises:
a third current mirror circuit having an output node and an input node coupled to the second output node of the first current mirror circuit;
a fourth switch coupled between the output node of the third current mirror circuit and the gate of the power transistor;
a fourth current mirror circuit having an output node and an input node coupled to the second output node of the second current mirror circuit; and
a fifth switch coupled between the output node of the fourth current mirror circuit and the gate of the power transistor.

6. The gate driver circuit according to claim 1, wherein the turn-off circuit further comprises a sixth switch coupled between the gate of the power transistor and a low-level line where a low voltage that corresponds to a low level of a gate voltage of the power transistor occurs.

7. The gate driver circuit according to claim 5, wherein the turn-off circuit further comprises a sixth switch coupled between the output node of the fourth current mirror circuit and a low-level line where a low voltage that corresponds to a low level of a gate voltage of the power transistor occurs.

8. The gate driver circuit according to claim 1, wherein the first current source comprises:
an output node;
a first constant current circuit coupled to the output node;
a seventh switch and a second constant current circuit coupled in series between the output node and a ground; and
an eighth switch and a third constant current circuit coupled in series between an output of the second constant current circuit and the ground.

9. The gate driver circuit according to claim 1, wherein the second current source comprises:
an output node;
a fourth constant current circuit coupled to the output node; and
a ninth switch and a fifth constant current circuit coupled in series between the output node and a ground.

10. The gate driver circuit according to claim 1, further comprising a first sensor structured to compare a gate-source voltage of the power transistor with a first threshold voltage,
wherein the control circuit makes the transition to the second period in response to a change in an output of the first sensor in the first period.

11. The gate driver circuit according to claim 1, further comprising a second sensor structured to compare an output voltage of the switching circuit with a second threshold voltage,
wherein the control circuit makes the transition to the third period in response to a change in an output of the second sensor in the second period.

12. The gate driver circuit according to claim 3, further comprising a third sensor structured to compare an output voltage of the switching circuit with a third threshold voltage,
wherein the control circuit makes a transition to a fourth period and turns on a third switch in response to a change in an output of the third sensor in the third period.

13. The gate driver circuit according to claim 1, monolithically integrated on a single semiconductor substrate.

14. A motor driving apparatus comprising:
a bridge circuit including a high-side transistor and a low-side transistor;
a high-side driver structured as the gate driver circuit according to claim 1, structured to drive the high-side transistor as the power transistor; and
a low-side driver structured as the gate driver circuit according to claim 1, structured to drive the low-side transistor as the power transistor.

15. An electronic device comprising:
a motor; and
the motor driving apparatus according to claim 14, structured to drive the motor.
